(19) United States
(12) Patent Application Publication
(10) Pub. No.: US 2025/0040362 A1
(43) Pub. Date: Jan. 30, 2025

(54) DISPLAY DEVICE

(71) Applicant: LG Display Co., Ltd., Seoul (KR)

(72) Inventors: Jung Eun LEE, Paju-si (KR); Hwan Keon LEE, Paju-si (KR); Hyun Seok GO, Paju-si (KR)

(73) Assignee: LG Display Co., Ltd., Seoul (KR)

(21) Appl. No.: 18/678,359

(22) Filed: May 30, 2024

(30) Foreign Application Priority Data
Jul. 28, 2023 (KR) 10-2023-0098778

(51) Int. Cl. H10K 59/124; H10K 59/80; H10K 77/10; H10K 102/00

(52) U.S. Cl. CPC H10K 59/124; H10K 59/873; H10K 77/111; H10K 2102/311

(57) ABSTRACT

A display device having a reduced bezel area is discussed. The display device can include a base substrate having a first area and a second area disposed outside the first area and being bent, a first driving transistor part disposed on the first area of the base substrate, a first light emitting element connected to the first driving transistor part in the first area, at least one first trench part formed by being recessed in the second area of the base substrate, a second driving transistor part disposed in the at least one first trench part, and a second light emitting element connected to the second driving transistor part in the second area. As such, the display device is configured to emit light even in the second area which is bent at the edge of the display panel.

### CROSS-REFERENCE TO RELATED APPLICATION

This application claims priority to Korean Patent Application No. 10-2023-0098778 filed in the Republic of Korea on Jul. 28, 2023, the entire contents of which is hereby expressly incorporated by reference into the present application.

### BACKGROUND

### Field

Embodiments of the present disclosure relate to a display device which has a reduced bezel area.

### Discussion of the Related Art

As the information age is entered, the field of displays which visually express electrical information signals has developed rapidly. As a result, various display devices with excellent performance such as thinness, light weight and low power consumption have been developed.

Specific examples of such display devices include a liquid crystal display device (LCD), a plasma display panel device (PDP), a field emission display device (FED), an organic light emitting display device (OLED), and so on.

Further, research is being actively conducted to provide a larger display area in a display device. For example, research is being actively conducted on narrow bezel technology for providing a wider and larger image to users by minimizing an edge part where an image is not outputted, while increasing a part where an image is outputted.

In order to improve the aesthetics of the display device, the edge part of a display panel is bent to form a curved surface. In this case, since it can be difficult to form a display surface in a bending area formed at the edge of the display panel, the corresponding bending area is defined as a bezel area rather than a display area. Therefore, as the area of a non-display surface increases, issues can arise in that it can be difficult to implement a narrow bezel, and the aesthetics of the display device can deteriorate.

### SUMMARY OF THE DISCLOSURE

In consideration of these issues associated with the related art and in order to address these issues, the inventors of the present disclosure have invented an improved display device capable of emitting light even in a bending area disposed at the edge of a display panel.

Embodiments of the present disclosure are directed to providing a display device which has a reduced bezel area by forming a trench structure in a bending area of a display panel and then disposing elements for emitting light in the trench structure.

Embodiments of the present disclosure are directed to providing a display device which has a reduced area forming a bezel and thus has improved aesthetics and a large display area, as even a bending area disposed at the edge of a display panel is formed to be capable of emitting light.

Embodiments of the present disclosure can provide a display device including a base substrate including a first area and a second area disposed outside the first area and being bent; a first driving transistor part disposed on the first area of the base substrate; a first light emitting element connected to the first driving transistor part in the first area; at least one first trench part formed by being recessed in the second area of the base substrate; a second driving transistor part disposed in the at least one first trench part; and a second light emitting element connected to the second driving transistor part in the second area.

According to embodiments of the present disclosure, it is possible to provide a display device capable of emitting light even in a bending area disposed at the edge of a display panel.

According to embodiments of the present disclosure, it is possible to provide a display device which has a reduced bezel area by forming a trench structure in a bending area of a display panel and then disposing elements for emitting light in the trench structure.

According to embodiments of the present disclosure, as even a bending area disposed at the edge of a display panel is formed to be capable of emitting light, it is possible to provide a display device which has a reduced area forming a bezel and thus has improved aesthetics and a large display area.

According to embodiments of the present disclosure, by forming the structures of driving transistor parts respectively disposed in a first area and a second area to be the same, it is possible to provide a display device having process optimization and improved properties.

These and other objects of the present application will become more readily apparent from the detailed description given hereinafter. However, it should be understood that the detailed description and specific examples, while indicating various embodiments of the present disclosure, are given by way of illustration only, since various changes and modifications within the spirit and scope of the present disclosure will become apparent to those skilled in the art from this detailed description.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a plan view of a display device according to an embodiment of the present disclosure.

FIG. 2 is a perspective view showing a state in which a second area of the display device shown in FIG. 1 is bent.

FIG. 3 is a cross-sectional view of the display device shown in FIG. 1.

FIG. 4 is a perspective view showing a trench structure which is formed in a base substrate of the display device according to the embodiment of the present disclosure.

FIGS. 5 to 10 are cross-sectional views of display devices with trench structures according to various examples of the present disclosure.

### DETAILED DESCRIPTION OF THE EMBODIMENTS

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein may be omitted or may be provided briefly when it is determined that the description can make the subject matter in some embodiments of the present disclosure rather unclear. The terms such as “including,” “having,” “containing,” “constituting,” “make up of” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A)” or “(B)” can be used herein to describe elements of the present disclosure. Each of these terms is not used to define essence, order, sequence, number of elements, etc., but is used merely to distinguish the corresponding element from other elements.

When it is mentioned that a first element “is connected or coupled to,” “contacts or overlaps,” etc. a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc. each other via a fourth element. Here, the second element can be included in at least one of two or more elements that “are connected or coupled to,” “contact or overlap,” etc. each other.

When time relative terms, such as “after,” “subsequent to,” “next,” “before” and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes, etc. are mentioned, it should be considered that numerical values for elements or features, or corresponding information (e.g., level, range, etc.) include a tolerance or error range that can be caused by various factors (e.g., process factors, internal or external impact, noise, etc.) even when a relevant description is not specified. Further, the term “may” fully encompasses all the meanings of the term “can.”

Features of various embodiments of the present disclosure can be partially or entirely coupled to or combined with each other and can be operated, linked, or driven together in various ways. Embodiments of the present disclosure can be carried out independently from each other, or can be carried out together in co-dependent or related relationship.

Hereinafter, various embodiments of the present disclosure will be described in detail with reference to the accompanying drawings. All the components of each display device according to all embodiments of the present disclosure are operatively coupled and configured.

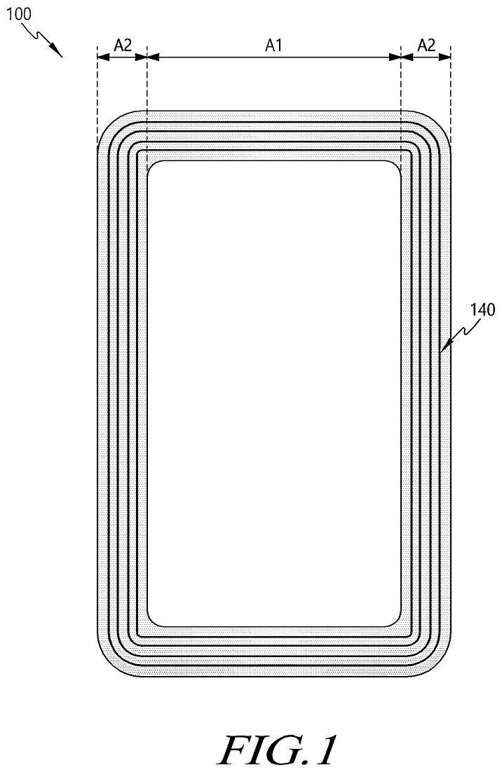

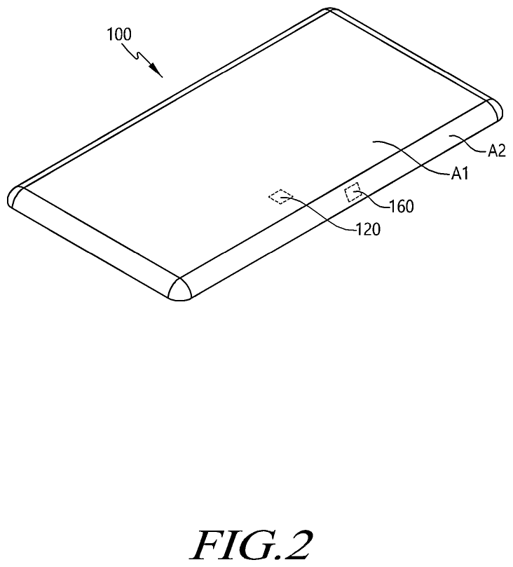

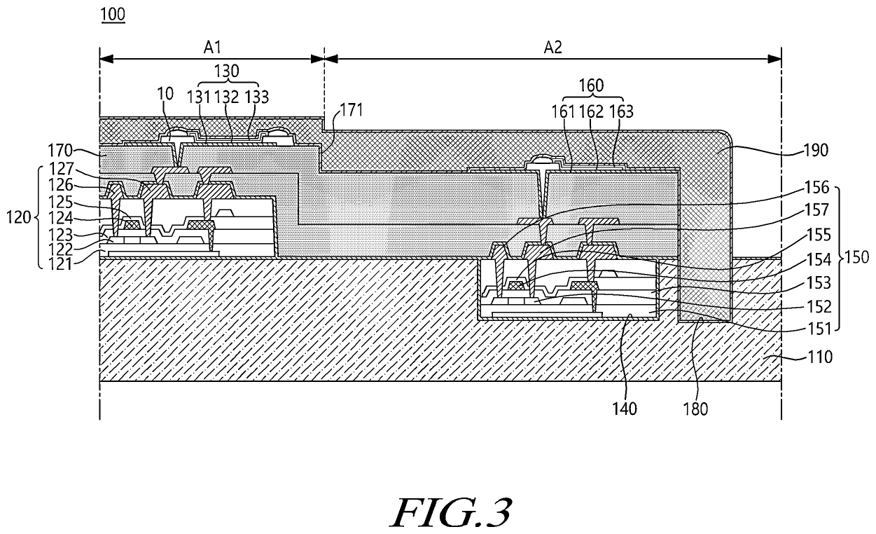

FIG. 1 is a plan view of a display device according to an embodiment of the present disclosure, FIG. 2 is a perspective view showing a state in which a second area of the display device shown in FIG. 1 is bent, and FIG. 3 is a cross-sectional view of the display device shown in FIG. 1.

Referring to FIGS. 1 to 3, a display device 100 according to the embodiment of the present disclosure can include a base substrate 110, a first driving transistor part 120, a first light emitting element 130, a first trench part 140, a second driving transistor part 150 and a second light emitting element 160.

The base substrate 110 can include a first area A1 and a second area A2 which is disposed outside the first area A1 and is bent. For example, the base substrate 110 can be formed in the shape of a quadrangular flat plate, and the second area A2 which forms an edge part can be bent with a preset curvature about the first area A1.

The base substrate 110 can be made of a plastic material to facilitate bending. For example, the base substrate 110 can be made of a plastic-based polymer material such as polyimide (PI). It is described in the embodiment that the base substrate 110 is made of polyimide, but the present disclosure is not limited thereto. For example, as the base substrate 110, various materials can be applied as long as they are materials with flexible properties such as polyethylene terephthalate (PET), polycarbonate (PC) and imide (PEI).

The first driving transistor part 120 is to drive the first light emitting element 130 by supplying a driving current to the first light emitting element 130, and can be disposed on the first area A1 of the base substrate 110. In other words, the first driving transistor part 120 can be disposed on the first area A1 where bending is not performed.

The first light emitting element 130 can be connected to the first driving transistor part 120 in the first area A1. Specifically, the first light emitting element 130 as an organic light emitting element (OLED) can include a first electrode 131, an organic compound layer 132 and a second electrode 133.

The first electrode 131 can be disposed on a planarization layer 170 which will be described later, to face the first driving transistor part 120, and can be connected to a first drain electrode 127 of the first driving transistor part 120 through a contact hole which is formed in the planarization layer 170. A bank layer 10 which is formed with an opening for defining a pixel can be disposed on the first electrode 131.

The organic compound layer 132 and the second electrode 133 can be formed to overlap the first electrode 131 on the opening of the bank layer 10. The organic compound layer 132 can be constituted by a hole injection layer (HIL), a hole transport layer (HTL), an emission layer (EML), an electron transport layer (ETL) and an electron injection layer (EIL). Accordingly, when driving voltages are applied to the first electrode 131 and the second electrode 133, holes which pass through the hole transport layer (HTL) and electrons which pass through the electron transport layer (ETL) move to the emission layer (EML) to form excitons, and as a result, the emission layer (EML) emits visible light.

When the display device 100 is a top emission type, the first electrode 131 can be an anode electrode and the second electrode 133 can be a cathode electrode. Conversely, when the display device 100 is a bottom emission type, the first electrode 131 can be a cathode electrode and the second electrode 133 can be an anode electrode.

At least one first trench part 140 can be provided, and can be formed by being recessed in the second area A2 of the base substrate 110. Namely, the first trench part 140 can be formed in the shape of a groove which is recessed in an area where the base substrate 110 is bent.

For example, when the base substrate 110 is formed in a quadrangular plate shape, the first trench part 140 can be formed to be recessed in four edge parts which form the second area A2. The first trench part 140 can be formed in a closed loop shape with both ends connected to each other, by being formed in a straight line in each edge part of the base substrate 110. The shape of the first trench part 140 is not limited thereto, and both ends of the first trench part 140 may not be connected but be separated from each other.

The first trench part 140 can be formed in the base substrate 110 through an etching process or a cutting process. The depth of the first trench part 140 is not limited, but can be 1 to 20 μm in consideration of the thickness of the base substrate 110. If the thickness of the first trench part 140 is less than 1 μm, it becomes challenging or difficult to dispose the second driving transistor part 150 in the first trench part 140, and if the thickness of the first trench part 140 exceeds 20 μm, the thickness of the base substrate 110 can become excessively large, making it challenging or difficult to implement the display device 100 to be compact.

The second driving transistor part 150 is to drive the second light emitting element 160 by supplying a driving current to the second light emitting element 160, and can be disposed in the first trench part 140. That is to say, the second driving transistor part 150 can be disposed on the second area A2 where bending is performed. A switching transistor which controls an amount of current to flow through a light emitting element can be connected to each of the first driving transistor part 120 and the second driving transistor part 150, and can be selectively turned on or off.

The second light emitting element 160 can be connected to the second driving transistor part 150 in the second area A2. Similarly to the first light emitting element 130, the second light emitting element 160 as an organic light emitting element (OLED) can include a first electrode 161, an organic compound layer 162 and a second electrode 163.

The first electrode 161 can be disposed on the planarization layer 170 to face the second driving transistor part 150, and can be connected to a first drain electrode 157 of the second driving transistor part 150 through a contact hole which is formed in the planarization layer 170. The bank layer 10 which is formed with an opening for defining a pixel can be disposed on the first electrode 161.

The organic compound layer 162 and the second electrode 163 can be formed on the opening of the bank layer 10 to overlap the first electrode 161. The organic compound layer 162 can be constituted by a hole injection layer (HIL), a hole transport layer (HTL), an emission layer (EML), an electron transport layer (ETL) and an electron injection layer (EIL). Accordingly, when driving voltages are applied to the first electrode 161 and the second electrode 163, holes which pass through the hole transport layer (HTL) and electrons which pass through the electron transport layer (ETL) move to the emission layer (EML) to form excitons, and as a result, the emission layer (EML) emits visible light.

In this way, as the second driving transistor part 150 and the second light emitting element 160 are provided in the first trench part 140 which is formed in the second area A2, it is possible to emit light even in an area which is located at the edges of the display device 100 and is bent.

Therefore, as an area which forms a bezel is reduced, it is possible to provide a display device which has improved aesthetics and a wide display area.

The first driving transistor part 120 according to the embodiment of the present disclosure can include a first buffer layer 121, a first active layer 122, a first gate insulating layer 123, a first gate electrode 124, a first intermediate insulating layer 125, a first source electrode 126, and the first drain electrode 127.

The first buffer layer 121 can be disposed on the first area A1 of the base substrate 110. For example, the first buffer layer 121 can be formed on the entire surface of the base substrate 110 which is located in the first area A1. The first buffer layer 121 can be formed as a single layer of silicon nitride (SiNx) or silicon oxide (SiOx) or a multilayer thereof. In this way, as the first buffer layer 121 is formed on the base substrate 110, adhesion between the base substrate 110 and members located thereon can be improved, and it is possible to block alkaline components, etc. flowing out from the base substrate 110.

The first active layer 122 can be disposed on the first buffer layer 121. For example, the first active layer 122 can include a source area which is connected to the first source electrode 126, a drain area which is connected to the first drain electrode 127, and a channel area which is disposed between the source area and the drain area and in which a channel is formed when driving the first driving transistor part 120.

The first gate insulating layer 123 can cover the first active layer 122 on the first buffer layer 121. For example, the first gate insulating layer 123 can be formed as a single layer of silicon nitride (SiNx) or silicon oxide (SiOx) or a multilayer thereof. Contact holes for connecting the first source electrode 126 and the first drain electrode 127 to the first active layer 122 can be formed in the first gate insulating layer 123.

The first gate electrode 124 can be disposed on the first gate insulating layer 123 to face the first active layer 122. For example, the first gate electrode 124 can be formed on the first gate insulating layer 123 at a location overlapping the channel area of the first active layer 122.

The first gate electrode 124 can be formed as a single layer made of any one or an alloy of molybdenum (Mo), copper (Cu), titanium (Ti), aluminum (Al), chromium (Cr), gold (Au), nickel (Ni) and neodymium (Nd) or a multilayer thereof.

The first intermediate insulating layer 125 can be formed on the first gate electrode 124. For example, the first intermediate insulating layer 125 can be formed as a single layer of silicon nitride (SiNx) or silicon oxide (SiOx) or a multilayer thereof. Contact holes for exposing the source area and the drain area of the first active layer 122 can be formed in the first intermediate insulating layer 125.

The first source electrode 126 can be disposed on the first intermediate insulating layer 125, and can be connected to one side of the first active layer 122. For example, the first source electrode 126 can be electrically connected to the first active layer 122 through the contact hole formed in the first intermediate insulating layer 125.

The first source electrode 126 can be made of a conductive metal material, and can be formed as a single layer of titanium (Ti) or aluminum (Al) or a multilayer thereof. Besides, the first source electrode 126 can be formed as a single layer made of any one or an alloy of molybdenum (Mo), copper (Cu), titanium (Ti), aluminum (Al), chromium (Cr), gold (Au), nickel (Ni) and neodymium (Nd) or a multilayer thereof.

The first drain electrode 127 can be disposed on the first intermediate insulating layer 125, and can be connected to the other side of the first active layer 122. For example, the first drain electrode 127 can be electrically connected to the first active layer 122 through the contact hole formed in the first intermediate insulating layer 125.

Similarly to the first source electrode 126, the first drain electrode 127 can be made of a conductive metal material, and can be formed as a single layer of titanium (Ti) or aluminum (Al) or a multilayer thereof. Besides, the first drain electrode 127 can be formed as a single layer made of any one or an alloy of molybdenum (Mo), copper (Cu), titanium (Ti), aluminum (Al), chromium (Cr), gold (Au), nickel (Ni) and neodymium (Nd) or a multilayer thereof.

The second driving transistor part 150 according to the embodiment of the present disclosure can include a second buffer layer 151, a second active layer 152, a second gate insulating layer 153, a second gate electrode 154, a second intermediate insulating layer 155, a second source electrode 156, and the second drain electrode 157.

The second buffer layer 151 can be disposed on the second area A2 of the base substrate 110. For example, the second buffer layer 151 can be formed on the entire surface of the base substrate 110 which is located in the second area A2, or can be formed from the contact point between the first area A1 and the second area A2 of the base substrate 110 to before an area where a second trench part 180 is formed. The second buffer layer 151 can be formed as a single layer of silicon nitride (SiNx) or silicon oxide (SiOx) or a multilayer thereof. In this way, as the second buffer layer 151 is formed in the second area A2 of the base substrate 110, adhesion of members located in the first trench part 140 can be improved.

The second active layer 152 can be disposed on the second buffer layer 151 which is located in the first trench part 140. For example, the second active layer 152 can include a source area which is connected to the second source electrode 156, a drain area which is connected to the second drain electrode 157, and a channel area which is disposed between the source area and the drain area and in which a channel is formed when driving the second driving transistor part 150.

The second gate insulating layer 153 can cover the second active layer 152 in the first trench part 140. For example, the second gate insulating layer 153 can be formed as a single layer of silicon nitride (SiNx) or silicon oxide (SiOx) or a multilayer thereof. Contact holes for connecting the second source electrode 156 and the second drain electrode 157 to the second active layer 152 can be formed in the second gate insulating layer 153.

The second gate electrode 154 can be disposed on the second gate insulating layer 153 to face the second active layer 152. For example, the second gate electrode 154 can be formed on the second gate insulating layer 153 at a location overlapping the channel area of the second active layer 152.

The second gate electrode 154 can be formed as a single layer made of any one or an alloy of molybdenum (Mo), copper (Cu), titanium (Ti), aluminum (Al), chromium (Cr), gold (Au), nickel (Ni) and neodymium (Nd) or a multilayer thereof.

The second intermediate insulating layer 155 can be formed on the second gate electrode 154. For example, the second intermediate insulating layer 155 can be formed as a single layer of silicon nitride (SiNx) or silicon oxide (SiOx) or a multilayer thereof. Contact holes for exposing the source area and the drain area of the second active layer 152 can be formed in the second intermediate insulating layer 155.

The second source electrode 156 can be disposed on the second intermediate insulating layer 155, and can be connected to one side of the second active layer 152. For example, the second source electrode 156 can be electrically connected to the second active layer 152 through the contact hole formed in the second intermediate insulating layer 155.

The second source electrode 156 can be made of a conductive metal material, and can be formed as a single layer of titanium (Ti) or aluminum (Al) or a multilayer thereof. Besides, the second source electrode 156 can be formed as a single layer made of any one or an alloy of molybdenum (Mo), copper (Cu), titanium (Ti), aluminum (Al), chromium (Cr), gold (Au), nickel (Ni) and neodymium (Nd) or a multilayer thereof.

The second drain electrode 157 can be disposed on the second intermediate insulating layer 155, and can be connected to the other side of the second active layer 152. For example, the second drain electrode 157 can be electrically connected to the second active layer 152 through the contact hole formed in the second intermediate insulating layer 155.

Similarly to the second source electrode 156, the second drain electrode 157 can be made of a conductive metal material, and can be formed as a single layer of titanium (Ti) or aluminum (Al) or a multilayer thereof. Besides, the second drain electrode 157 can be formed as a single layer made of any one or an alloy of molybdenum (Mo), copper (Cu), titanium (Ti), aluminum (Al), chromium (Cr), gold (Au), nickel (Ni) and neodymium (Nd) or a multilayer thereof.

The display device 100 according to the embodiment of the present disclosure can further include the planarization layer 170, the second trench part 180 and an encapsulation layer 190.

The planarization layer 170 can be an organic material layer for planarizing the tops of the first driving transistor part 120 and the second driving transistor part 150. For example, the planarization layer 170 can be formed of an organic material such as acryl resin, epoxy resin, phenolic resin, polyamide resin and polyimide resin.

The planarization layer 170 can be disposed between the first driving transistor part 120 and the second driving transistor part 150 and the first light emitting element 130 and the second light emitting element 160 on the base substrate 110. In other words, the planarization layer 170 can be formed to cover the first driving transistor part 120 and the second driving transistor part 150 on the base substrate 110, and the first light emitting element 130 and the second light emitting element 160 can be disposed on the planarization layer 170.

The planarization layer 170 can include at least one layer. The planarization layer 170 can be made of a single layer or a multilayer depending on the number of layers of the first drain electrode 127 and the second drain electrode 157. For example, as shown in FIG. 3, when the first drain electrode 127 and the second drain electrode 157 are formed as two layers, the planarization layer 170 can also be formed as two layers.

The contact holes for exposing the first drain electrode 127 and the second drain electrode 157 of the first driving transistor part 120 and the second driving transistor part 150 can be formed in the planarization layer 170. Accordingly, the first electrode 131 and the first electrode 161 disposed on the planarization layer 170 can be electrically connected to the first drain electrode 127 and the second drain electrode 157 through the contact holes, respectively.

The height of the planarization layer 170 can be determined such that one part of the planarization layer 170 formed in the first area A1 is higher than the other part of the planarization layer 170 formed in the second area A2, and thus, and a step 171 can be formed between the first area A1 and the second area A2. In other words, because the second driving transistor part 150 is disposed in the first trench part 140 formed in the second area A2, the second driving transistor part 150 can be located lower than the first driving transistor part 120. Due to such a height difference between the first driving transistor part 120 and the second driving transistor part 150, the step 171 can be formed between the first area A1 and the second area A2 when forming the planarization layer 170.

In this way, as the step 171 is formed between the first area A1 and the second area A2, the bending of the second area A2 can be performed more smoothly.

The second trench part 180 can be disposed to be spaced apart from the first trench part 140, and can be formed to be recessed in the second area A2. For example, at least one second trench part 180 can be provided, and can be disposed outside the first trench part 140. Namely, the second trench part 180 can be formed to be disposed outside the first trench part 140.

The depths of the first trench part 140 and the second trench part 180 can be the same. In this way, when the first trench part 140 and the second trench part 180 have the same depth, because the first trench part 140 and the second trench part 180 can be formed using one mask during an etching process, an advantage is provided in that manufacturing is easy.

The encapsulation layer 190 is to prevent moisture and foreign substances from penetrating into the first light emitting element 130 and the second light emitting element 160, and can be a multilayer in which an inorganic material and an organic material are alternately formed.

The encapsulation layer 190 can be disposed on the planarization layer 170 to cover the first light emitting element 130 and the second light emitting element 160, and the end thereof can be disposed in the second trench part 180. In this way, as the end of the encapsulation layer 190 is disposed in the second trench part 180, the flow of an organic material which constitutes the encapsulation layer 190 can be blocked. Hence, it is possible to prevent the encapsulation layer 190 from being exposed to the outside of the display device 100 or from invading a pad electrode. Since there is no need to separately install, around the encapsulation layer 190, a dam for blocking the flow of an organic material included in the encapsulation layer 190, a process can be simplified and a narrow bezel can be implemented.

In order to effectively prevent moisture and foreign substances from penetrating, the encapsulation layer 190 can cover both the top and the side of the planarization layer 170. To this end, the end of the planarization layer 170 can be formed not to traverse the second trench part 180.

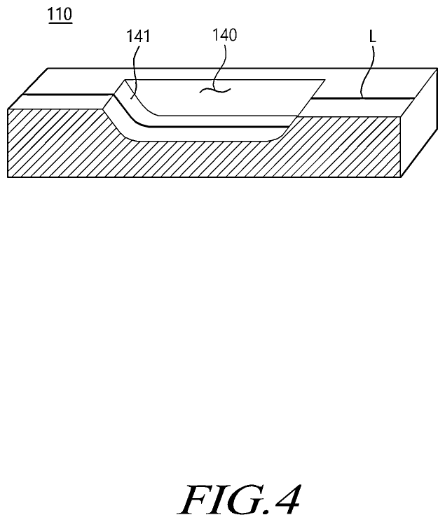

FIG. 4 is a perspective view showing a trench structure which is formed in a base substrate of a display device according to the embodiment of the present disclosure. The display device can be any display device discussed in the present specification.

Referring to FIG. 4, the inner surface of the base substrate 110 on which the first trench part 140 is formed can be formed to have an inclined surface 141 so that the width of the first trench part 140 gradually narrows from the top to the bottom thereof.

In this way, when the inclined surface 141 is formed on the inner surface of the base substrate 110 where the first trench part 140 is formed, it is possible to prevent a wiring L from being bent and cut off. That is to say, since the second driving transistor part 150 is disposed in the first trench part 140, a gate wiring and various signal wirings can be disposed in the first trench part 140. Since these wirings L are formed to a very thin thickness, they can be easily cut off by even a small external force.

For example, when the inner surface of the base substrate 110 on which the first trench part 140 is formed is formed at 90°, the wiring L can be bent at 90° on both sides of the first trench part 140, which can cause the cut-off of the wiring L. Thus, by forming the inclined surface 141 with a taper shape on the inner surface of the base substrate 110 where the first trench part 140 is formed, the problem of cut-off of the wiring L can be solved.

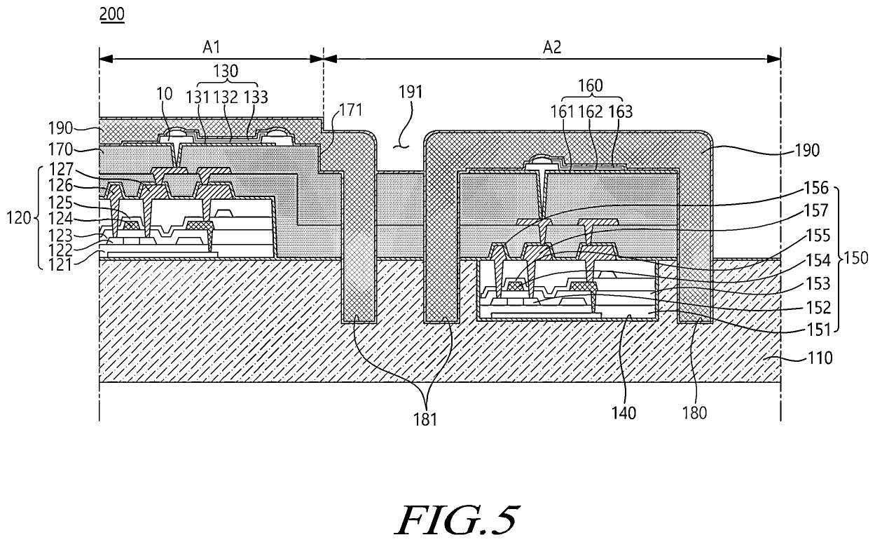

FIG. 5 is a cross-sectional view of a display device with a trench structure according to another embodiment of the present disclosure. In the present embodiment, description will be made mainly on differences from the embodiment described above. That is, the display device herein can have the same or similar structures, components and/or configurations of any display device discussed in the present specification.

Referring to FIG. 5, a display device 200 can further include one or more third trench parts 181 which are formed by being recessed in the second area A2 and are disposed between the first light emitting element 130 and the second light emitting element 160.

The third trench parts 181 can be formed to the same depth as the second trench part 180. For example, the third trench parts 181 can be formed by being recessed into the planarization layer 170 and the base substrate 110. Two third trench parts 181 can be provided to be spaced apart from each other, and the encapsulation layer 190 can be disposed in the third trench parts 181. The encapsulation layer 190 which is located in the second area A2 can include a bending groove 191 which is formed by being recessed in a direction toward the base substrate 110, and the third trench parts 181 can be disposed on both sides, respectively, of the bending groove 191 so as not to interfere with the bending groove 191. The encapsulation layer 190 may not exist between the two third trench parts 181.

By this structure, the encapsulation layer 190 can be divided about the bending groove 191 in the second area A2 where bending is performed. In this way, when the encapsulation layer 190 is divided in the second area A2, bending can be more effectively performed in the second area A2 about the bending groove 191.

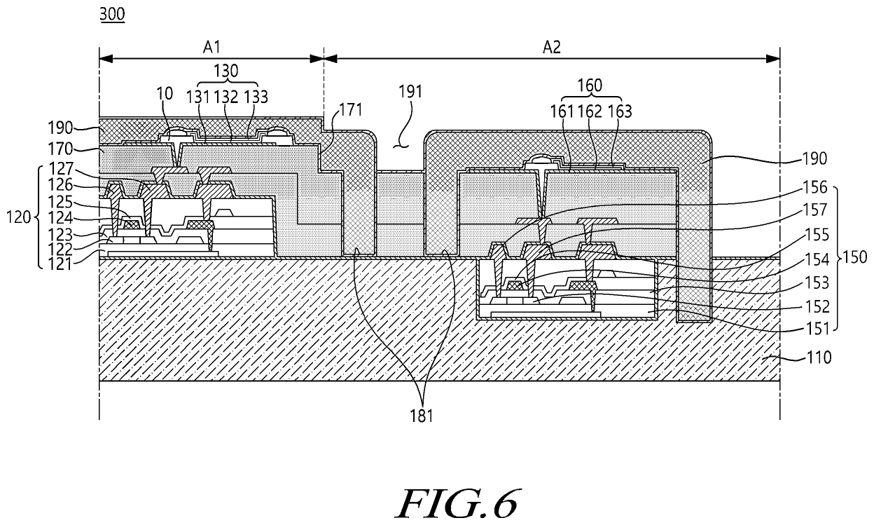

FIG. 6 is a cross-sectional view of a display device with a trench structure according to another embodiment of the present disclosure. In the present embodiment, description will be made mainly on differences from the embodiments described above. That is, the display device herein can have the same or similar structures, components and/or configurations of any display device discussed in the present specification.

Referring to FIG. 6, a display device 300 can further include one or more third trench parts 181 which are formed by being recessed in the second area A2 and are disposed between the first light emitting element 130 and the second light emitting element 160.

The third trench parts 181 can be formed to have a shorter depth than the second trench part 180. For example, the third trench parts 181 can be formed by being recessed in the planarization layer 170. Two third trench parts 181 can be provided to be spaced apart from each other, and the encapsulation layer 190 can be disposed in the third trench parts 181. The encapsulation layer 190 which is located in the second area A2 can include a bending groove 191 which is formed by being recessed in a direction toward the base substrate 110, and the third trench parts 181 can be disposed on both sides, respectively, of the bending groove 191 so as not to interfere with the bending groove 191.

By this structure, the encapsulation layer 190 can be divided about the bending groove 191 in the second area A2 where bending is performed, and the encapsulation layer 190 may not exist between the two third trench parts 181.

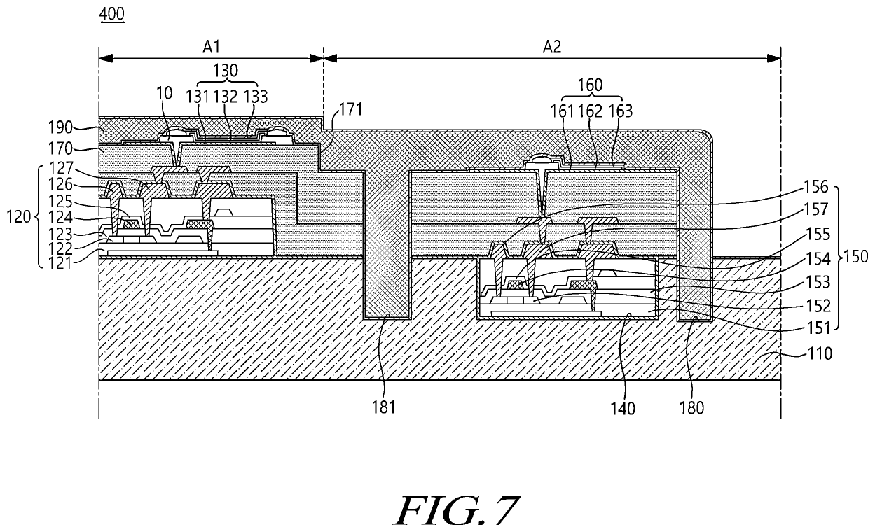

FIG. 7 is a cross-sectional view of a display device with a trench structure according to another embodiment of the present disclosure. In the present embodiment, description will be made mainly on differences from the embodiments described above. That is, the display device herein can have the same or similar structures, components and/or configurations of any display device discussed in the present specification.

Referring to FIG. 7, a display device 400 can further include a third trench part 181 which is formed by being recessed in the second area A2 and is disposed between the first light emitting element 130 and the second light emitting element 160.

For example, the third trench part 181 can be formed by being recessed into the planarization layer 170 and the base substrate 110 to the same depth as the second trench part 180. The encapsulation layer 190 can be disposed in the third trench part 181. Accordingly, the planarization layer 170 can be divided by the third trench part 181 in the second area A2, and the encapsulation layer 190 which is located in the third trench part 181 can form a structure which extends from the encapsulation layer 190 of the first area A1 and the encapsulation layer 190 of the second area A2.

In this way, as the encapsulation layer 190 is further provided in the third trench part 181 which is formed by being recessed into the planarization layer 170 and the base substrate 110, it is possible to prevent more effectively moisture and foreign substances from penetrating into the first light emitting element 130 and the second light emitting element 160.

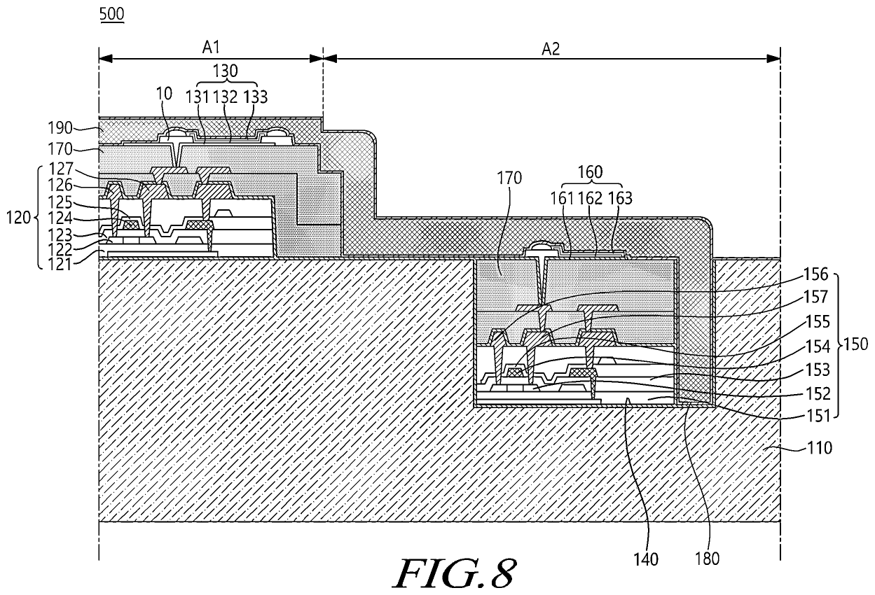

FIG. 8 is a cross-sectional view of a display device with a trench structure according to another embodiment of the present disclosure. In the present embodiment, description will be made mainly on differences from the embodiments described above. That is, the display device herein can have the same or similar structures, components and/or configurations of any display device discussed in the present specification.

Referring to FIG. 8, the planarization layer 170 of a display device 500 can be disposed in the first trench part 140 in the second area A2. For example, as the planarization layer 170 in the second area A2 is formed to be disposed in only the first trench part 140, a structure in which the planarization layer 170 in the second area A2 is separated from the planarization layer 170 located in the first area A1 can be formed.

By this structure, the encapsulation layer 190 disposed on the planarization layer 170 can be located lower in the second area A2 than in the first area A1. In this way, when the height of the encapsulation layer 190 is formed to be lowest in the second area A2 where bending is performed, bending can be performed more effectively in the second area A2.

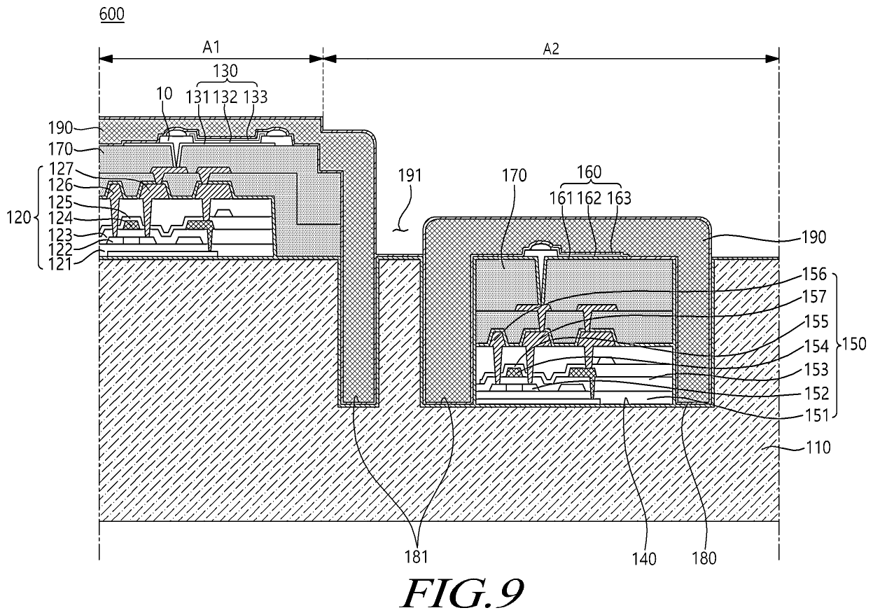

FIG. 9 is a cross-sectional view of a display device with a trench structure according to another embodiment of the present disclosure. In the present embodiment, description will be made mainly on differences from the embodiments described above. That is, the display device herein can have the same or similar structures, components and/or configurations of any display device discussed in the present specification.

Referring to FIG. 9, a display device 600 can further include one or more third trench parts 181 which are formed by being recessed in the second area A2 and are disposed between the first light emitting element 130 and the second light emitting element 160.

The third trench parts 181 can be formed to the same depth as the second trench part 180. For example, the third trench parts 181 can be formed by being recessed into the base substrate 110 to the same depth as the second trench part 180. Two third trench parts 181 can be provided to be spaced apart from each other, and the encapsulation layer 190 can be disposed in the third trench parts 181. The encapsulation layer 190 which is located in the second area A2 can include a bending groove 191 which is formed by being recessed in a direction toward the base substrate 110, and the third trench parts 181 can be disposed on both sides, respectively, of the bending groove 191 so as not to interfere with the bending groove 191.

The planarization layer 170 according to the embodiment of the present disclosure can be disposed in the first trench part 140 in the second area A2. The planarization layer 170 and the encapsulation layer 190 may not exist between the two third trench parts 181.

By this structure, the encapsulation layer 190 can be divided about the bending groove 191 in the second area A2 where bending is performed. Since the planarization layer 170 located in the second area A2 is disposed in only the first trench part 140, the height of the encapsulation layer 190 disposed in the second area A2 can be lower than the height of the encapsulation layer 190 disposed in the first area A1. Accordingly, bending can be performed more effectively about the bending groove 191 in the second area A2.

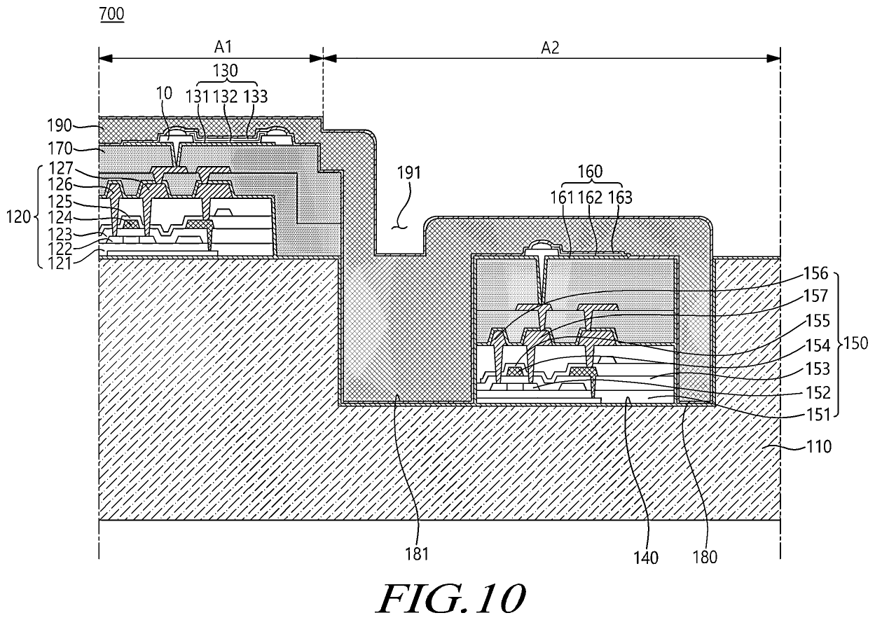

FIG. 10 is a cross-sectional view of a display device with a trench structure according to another embodiment of the present disclosure. In the present embodiment, description will be made mainly on differences from the embodiments described above. That is, the display device herein can have the same or similar structures, components and/or configurations of any display device discussed in the present specification.

Referring to FIG. 10, a display device 700 can further include one third trench part 181 which is formed by being recessed in the second area A2 and is disposed between the first light emitting element 130 and the second light emitting element 160.

The third trench part 181 can be formed to the same depth as the second trench part 180. For example, one third trench part 181 can be provided and be formed by being recessed into the base substrate 110. The encapsulation layer 190 disposed on the planarization layer 170 in the first area A1 and the second area A2 can have a structure in which the encapsulation layer 190 extends to be disposed in the third trench part 181 and the second trench part 180. The encapsulation layer 190 located in the third trench part 181 can include a bending groove 191 which is formed as the upper portion of the encapsulation layer 190 is partially recessed in a direction toward the base substrate 110.

The planarization layer 170 according to the embodiment can be disposed in the first trench part 140 in the second area A2, and may not exist in the third trench part 181.

As such, when the planarization layer 170 located in the second area A2 is disposed in only the first trench part 140, the height of the encapsulation layer 190 disposed in the second area A2 can be lower than the height of the encapsulation layer 190 disposed in the first area A1. Accordingly, bending can be performed more effectively about the bending groove 191 in the second area A2.

A brief description of the embodiments of the disclosed technology described above is as follows.

Embodiments of the present disclosure can provide a display device including a base substrate including a first area and a second area which is disposed outside the first area and is bent; a first driving transistor part disposed on the first area of the base substrate; a first light emitting element connected to the first driving transistor part in the first area; at least one first trench part formed by being recessed in the second area of the base substrate; a second driving transistor part disposed in the first trench part; and a second light emitting element connected to the second driving transistor part in the second area.

According to the embodiments of the present disclosure, the display device can further include a planarization layer disposed between the first driving transistor part and the second driving transistor part and the first light emitting element and the second light emitting element on the base substrate, and including at least one layer.

According to the embodiments of the present disclosure, a height of the planarization layer can be determined such that a portion of the planarization layer formed in the first area is higher than a portion of the planarization layer formed in the second area, and a step can be formed between the first area and the second area.

According to the embodiments of the present disclosure, the planarization layer can be disposed in the first trench part in the second area.

According to the embodiments of the present disclosure, the display device can further include at least one second trench part disposed to be spaced apart from the first trench part, and formed by being recessed in the second area; and an encapsulation layer disposed on the planarization layer to cover the first light emitting element and the second light emitting element, and having an end which is disposed in the second trench part.

According to the embodiments of the present disclosure, a portion of the encapsulation layer which is formed in the second area can include a bending groove which is recessed in a direction in which the base substrate is located.

According to the embodiments of the present disclosure, an end of the planarization layer can be formed not to traverse the second trench part.

According to the embodiments of the present disclosure, the second trench part can be disposed outside the first trench part.

According to the embodiments of the present disclosure, the first trench part and the second trench part can have the same depth.

According to the embodiments of the present disclosure, the display device can further include at least one third trench part formed by being recessed in the second area, and disposed between the first light emitting element and the second light emitting element.

According to the embodiments of the present disclosure, the third trench part can be formed by being recessed into the planarization layer.

According to the embodiments of the present disclosure, the third trench part can be formed by being recessed into the planarization layer and the base substrate.

According to the embodiments of the present disclosure, two third trench parts can be disposed to be spaced apart from each other, and the encapsulation layer can be disposed in the third trench parts.

According to the embodiments of the present disclosure, the encapsulation layer may not exist between the two third trench parts.

According to the embodiments of the present disclosure, the planarization layer and the encapsulation layer may not exist between the two third trench parts.

According to the embodiments of the present disclosure, the planarization layer can be divided by the third trench part in the second area.

According to the embodiments of the present disclosure, the first driving transistor part can include a first buffer layer disposed in the first area of the base substrate; a first active layer disposed on the first buffer layer; a first gate insulating layer covering the first active layer on the first buffer layer; a first gate electrode disposed on the first gate insulating layer to face the first active layer; a first intermediate insulating layer formed on the first gate electrode; a first source electrode disposed on the first intermediate insulating layer, and connected to one side of the first active layer; and a first drain electrode disposed on the first intermediate insulating layer, and connected to another side of the first active layer.

According to the embodiments of the present disclosure, the second driving transistor part can include a second buffer layer disposed in the second area of the base substrate; a second active layer disposed on the second buffer layer located in the first trench part; a second gate insulating layer covering the second active layer in the first trench part; a second gate electrode disposed on the second gate insulating layer to face the second active layer; a second intermediate insulating layer formed on the second gate electrode; a second source electrode disposed on the second intermediate insulating layer, and connected to one side of the second active layer; and a second drain electrode disposed on the second intermediate insulating layer, and connected to another side of the second active layer.

According to the embodiments of the present disclosure, the first trench part can have a depth of 1 to 20 μm.

According to the embodiments of the present disclosure, an inner surface of the base substrate on which the first trench part is formed can have an inclined surface whose width gradually narrows from top to bottom.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present disclosure. The above description and the accompanying drawings provide an example of the technical idea of the present disclosure for illustrative purposes only. For example, the disclosed embodiments are intended to illustrate the scope of the technical idea of the present disclosure.

What is claimed is:

1. A display device comprising:
a base substrate including a first area and a second area, the second area being disposed outside the first area and being bent;
a first driving transistor part disposed on the first area of the base substrate;
a first light emitting element connected to the first driving transistor part in the first area;
at least one first trench part formed by being recessed in the second area of the base substrate;
a second driving transistor part disposed in the at least one first trench part; and
a second light emitting element connected to the second driving transistor part in the second area.

2. The display device of claim 1, further comprising:
a planarization layer disposed between the first driving transistor part and the second driving transistor part and the first light emitting element and the second light emitting element on the base substrate.

3. The display device of claim 2, wherein a height of the planarization layer is determined so that a portion of the planarization layer formed in the first area is higher than a portion of the planarization layer formed in the second area, and a step is formed between the first area and the second area.

4. The display device of claim 2, wherein the planarization layer is disposed in the at least one first trench part in the second area.

5. The display device of claim 2, further comprising:
at least one second trench part disposed to be spaced apart from the at least one first trench part, and formed by being recessed in the second area; and
an encapsulation layer disposed on the planarization layer to cover the first light emitting element and the second light emitting element, the encapsulation layer having an end disposed in the at least one second trench part.

6. The display device of claim 5, wherein a portion of the encapsulation layer which is formed in the second area includes a bending groove recessed in a direction in which the base substrate is located.

7. The display device of claim 5, wherein an end of the planarization layer is formed not to traverse the at least one second trench part.

8. The display device of claim 5, wherein the at least one second trench part is disposed outside the at least one first trench part.

9. The display device of claim 5, wherein the at least one first trench part and the at least one second trench part have a same depth.

10. The display device of claim 1, further comprising:
at least one third trench part formed by being recessed in the second area, and disposed between the first light emitting element and the second light emitting element.

11. The display device of claim 10, wherein the at least one third trench part is formed by being recessed into the planarization layer.

12. The display device of claim 10, wherein the at least one third trench part is formed by being recessed into the planarization layer and the base substrate.

13. The display device of claim 10, wherein the at least one third trench part includes two third trench parts disposed to be spaced apart from each other, and
the encapsulation layer is disposed in the two third trench parts.

14. The display device of claim 13, wherein the encapsulation layer does not exist between the two third trench parts.

15. The display device of claim 13, wherein the planarization layer and the encapsulation layer do not exist between the two third trench parts.

16. The display device of claim 10, wherein the planarization layer is divided by the at least one third trench part in the second area.

17. The display device of claim 1, wherein the first driving transistor part comprises:
a first buffer layer disposed in the first area of the base substrate;
a first active layer disposed on the first buffer layer;
a first gate insulating layer covering the first active layer on the first buffer layer;
a first gate electrode disposed on the first gate insulating layer to face the first active layer;
a first intermediate insulating layer disposed on the first gate electrode;
a first source electrode disposed on the first intermediate insulating layer, and connected to one side of the first active layer; and
a first drain electrode disposed on the first intermediate insulating layer, and connected to another side of the first active layer.

18. The display device of claim 1, wherein the second driving transistor part comprises:
a second buffer layer disposed in the second area of the base substrate;
a second active layer disposed on the second buffer layer located in the at least one first trench part;
a second gate insulating layer covering the second active layer in the at least one first trench part;
a second gate electrode disposed on the second gate insulating layer to face the second active layer;
a second intermediate insulating layer formed on the second gate electrode;
a second source electrode disposed on the second intermediate insulating layer, and connected to one side of the second active layer; and
a second drain electrode disposed on the second intermediate insulating layer, and connected to another side of the second active layer.

19. The display device of claim 1, wherein the at least one first trench part has a depth of about 1 μm to 20 μm.

20. The display device of claim 1, wherein an inner surface of the base substrate on which the at least one first trench part is formed has an inclined surface having width gradually narrowing from top to bottom.
